(19) United States
(12) Patent Application Publication
(10) Pub. No.: US 2021/0295142 A1
(43) Pub. Date: Sep. 23, 2021

(54) IMAGE PROCESSING APPARATUS

(71) Applicants: KABUSHIKI KAISHA TOSHIBA, Tokyo (JP); Toshiba Electronic Devices & Storage Corporation, Tokyo (JP)

(72) Inventor: Nau OZAKI, Kawasaki Kanagawa (JP)

(73) Assignees: KABUSHIKI KAISHA TOSHIBA, Tokyo (JP); Toshiba Electronic Devices & Storage Corporation, Tokyo (JP)

(21) Appl. No.: 16/992,506

(22) Filed: Aug. 13, 2020

(30) Foreign Application Priority Data
Mar. 17, 2020 (JP) 2020-046914

(51) Int. Cl. G06N 3/063; G06N 3/04; G06T 1/60; G11C 11/4063

(52) U.S. Cl. CPC G06N 3/063; G11C 11/4063; G06T 1/60; G06N 3/0481

(57) ABSTRACT

An image processing apparatus according to an embodiment includes an image signal processor configured to receive image data, a state buffer provided in the image signal processor, and a recursive neural network processor configured to perform a recursive neural network operation using at least one of a plurality of pixel data in the image data and an operation result of the recursive neural network operation stored in the state buffer.

### CROSS-REFERENCE TO RELATED APPLICATION

This application is based upon and claims the benefit of priority from Japanese Patent Application No. 2020-046914 filed Mar. 17, 2020; the entire contents of which are incorporated herein by reference.

### FIELD

An embodiment described herein relates generally to an image processing apparatus.

### BACKGROUND

There has been a technique for realizing recognition processing for image data or the like, by a neural network. For example, a kernel operation in a convolutional neural network (hereinafter referred to as CNN) is performed after entire image data of an image is held in a frame buffer in an off-chip memory such as a DRAM while sliding a window of a predetermined size for the held entire image data.

Accordingly, it takes time to store the entire image data in the off-chip memory and access the off-chip memory for writing and reading out a feature map performed for each kernel operation. Thus, a latency of a CNN operation is large. In a device such as an image signal processor, a latency is desired to be small.

To reduce the latency of a CNN operation, a line buffer of a size smaller than the size of the frame buffer can also be used. However, an access to the line buffer for a kernel operation is frequently made. Thus, a memory capable of a high-speed access needs to be used for the line buffer, resulting in an increased cost of the image processing apparatus.

### BRIEF DESCRIPTION OF THE DRAWINGS

FIG. 1 depicts an image processing apparatus according to an embodiment;

FIG. 2 depicts a processing content of an image signal processor according to the embodiment;

FIG. 3 depicts a configuration of the image signal processor according to the embodiment;

FIG. 4 depicts a recursive neural network processor according to the embodiment;

FIG. 5 depicts conversion from input image data into stream data according to the embodiment;

FIG. 6 depicts a processing order by a recursive neural network cell of a plurality of pixel values included in the input image data according to the embodiment;

FIG. 7 depicts a processing order by a line end cell of respective output values in a last column of rows according to Modification 1;

FIG. 8 depicts a processing order by a recursive neural network cell of a plurality of pixel values included in input image data according to Modification 2;

FIG. 9 depicts a receptive field in a convolutional neural network;

FIG. 10 depicts a receptive field in the embodiment;

FIG. 11 depicts a difference between respective ranges of receptive fields in the convolutional neural network and a recursive neural network;

FIG. 12 depicts an input step of the recursive neural network cell according to Modification 2; and

FIG. 13 depicts a setting range of a receptive field according to Modification 2.

### DETAILED DESCRIPTION

According to one or more embodiments, an image processing apparatus includes an image signal processor configured to receive image data, a state buffer provided in the image signal processor, and a recursive neural network processor configured to perform a recursive neural network operation using at least one of a plurality of pixel data in the image data and an operation result of the recursive neural network operation stored in the state buffer.

An embodiment will be described below with reference to the drawings.

### (Configuration)

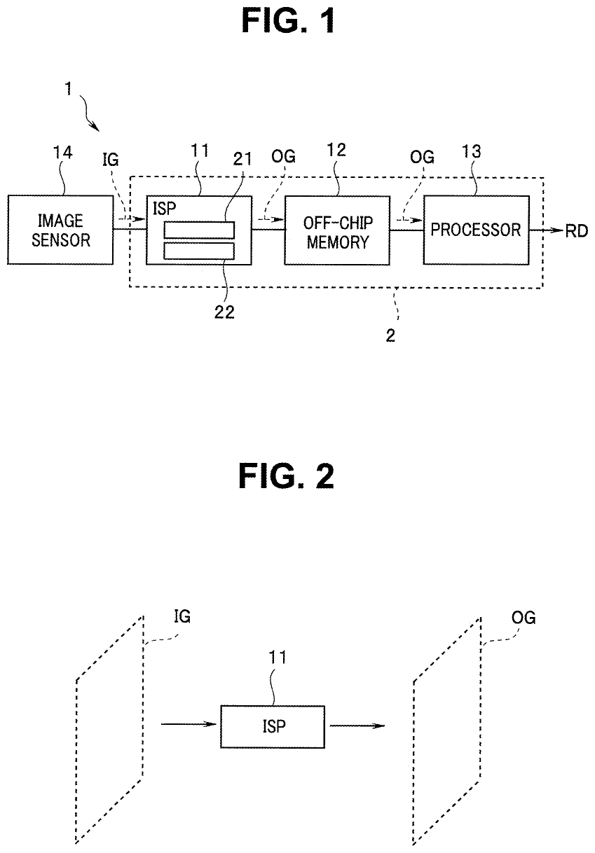

FIG. 1 is a block diagram of an image processing apparatus according to the embodiment. An image processing system 1 using the image processing apparatus according to the present embodiment processes image data from a camera device, to perform processing such as image recognition, and outputs information about a result of the processing.

The image processing system 1 includes an image signal processor (hereinafter referred to as ISP 11, an off-chip memory 12, and a processor 13.

The ISP 11 is connected to the camera device (not illustrated) by an interface according to an MIPI (mobile industry processor interface) CSI (camera serial interface) standard or the like. The ISP 11 receives an image pickup signal from an image sensor 14 in the camera device, to perform predetermined processing for the image pickup signal, and outputs data representing a result of the predetermined processing. In other words, a plurality of pixel data in image data are sequentially inputted to the ISP 11 as a processor. The ISP 11 receives an image pickup signal (hereinafter referred to as input image data) IG from the image sensor 14 as an image pickup device, and outputs image data (hereinafter referred to as output image data) OG as result data. For example, the ISP 11 subjects the input image data IG to noise removal or the like, and outputs output image data OG having no noise or the like.

Note that all input image data IG from the image sensor 14 are inputted to the ISP 11 so that an RNN operation, described below, may be performed for all the input image data IG or an RNN operation, described below, may be performed for some of the input image data 1G.

The ISP 11 includes a state buffer 21 and an RNN cell processor 22 configured to repeatedly perform a predetermined operation by a recurrent neural network (hereinafter referred to as RNN). A configuration of the ISP 11 will be described below.

The off-chip memory 12 is a memory such as a DRAM. The output image data OG to be generated in the ISP 11 and outputted from the ISP 11 is stored in the off-chip memory 12.

The processor 13 performs recognition processing or the like based on the output image data OG stored in the off-chip memory 12. The processor 13 outputs result data RD by recognition processing or the like. Therefore, the ISP 11, the off-chip memory 12, and the processor 13 constitute an image recognition apparatus (indicated by a dotted line in FIG. 1) configured to perform image recognition processing or the like for an image, for example.

FIG. 2 is a diagram for describing a processing content of the ISP 11. As illustrated in FIG. 2, the ISP 11 performs predetermined processing such as noise removal for the input image data IG from the image sensor 14 using the RNN cell processor 22 (described below), to generate the output image data OG.

For example, in the image recognition apparatus 2, when the processor 13 performs recognition processing or the like based on the output image data OG, an accuracy of the recognition processing or the like in the processor 13 can be expected to be improved because the output image data OG is data from which noise has been removed.

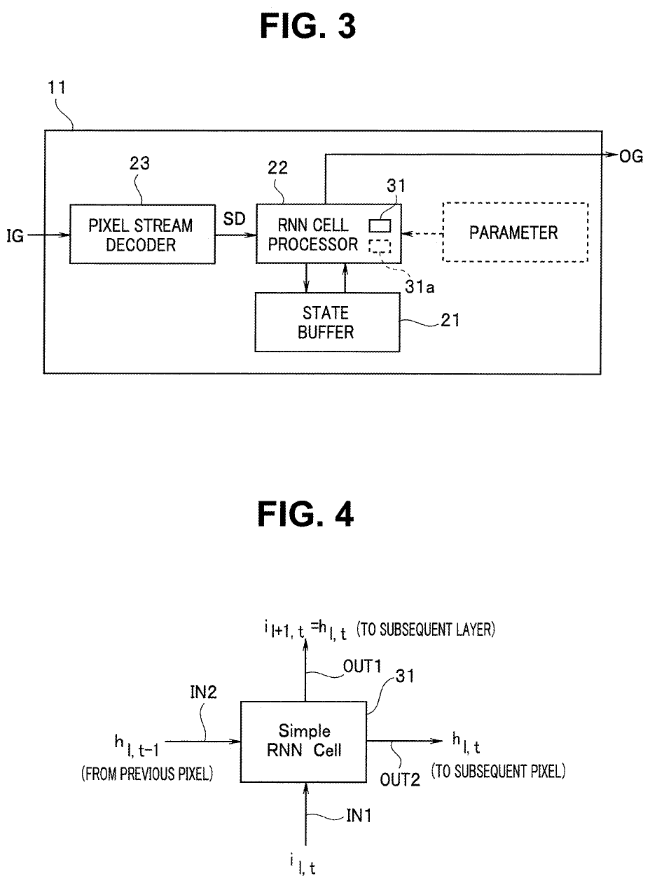

FIG. 3 is a block diagram illustrating a configuration of the ISP 11. FIG. 4 is a configuration diagram of the RNN cell processor 22. The ISP 11 includes the state buffer 21, the RNN cell processor 22, and a pixel stream decoder 23. The pixel stream decoder 23 is a circuit configured to convert the input image data IG into stream data SD and output the stream data SD to the RNN cell processor 22.

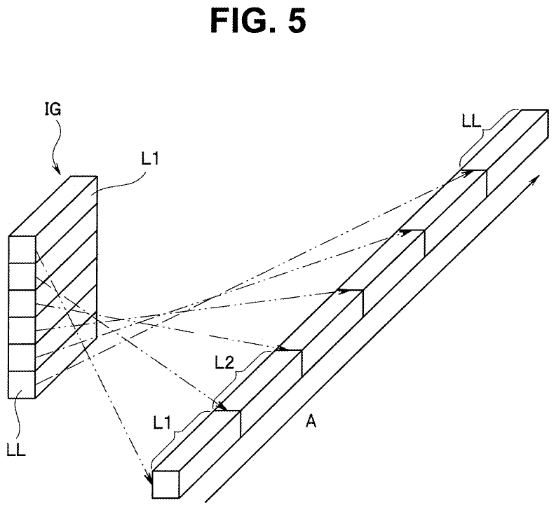

FIG. 5 is a diagram for describing conversion from input image data IG into stream data SD. To simplify the description, an image of the input image data IG is composed of image data in six rows in FIG. 5. Each of the rows includes a plurality of pixel data. In other words, the image is composed of pixel data in a plurality of rows (here, six rows) and a plurality of columns.

When receiving input image data IG from the image sensor 14, the pixel stream decoder 23 converts a plurality of pixel data in the received input image data IG into stream data SD in a predetermined order.

The pixel stream decoder 23 generates from input image data IG stream data SD composed of a plurality of pixel data included in row data L1 from a pixel in a first column of a first row (i.e., a pixel at a left end of an uppermost row) to a pixel in a last column of the first row (i.e., a pixel at a right end of the uppermost row), row data L2 from a pixel in a first column of a second row (i.e., a pixel at a left end of a second row from the top) to a pixel in a last column of the second row (i.e., a pixel at a right end of the second row) subsequently to the row data L1 . . . , a data column LL from a pixel in a first column of a sixth row as a last row (i.e., a pixel at a left end of a lowermost row) to a pixel in a last column of the sixth row (i.e., a pixel at a right end of the lowermost row), and outputs the generated stream data SD.

Therefore, the pixel stream decoder 23 is a circuit configured to convert input image data IG into stream data SD and output the stream data SD to the RNN cell processor 22.

As illustrated in FIG. 4, the RNN cell processor 22 is a processor including one RNN cell 31. The RNN cell 31 is a simple RNN cell, and is a hardware circuit configured to output hidden states respectively obtained by performing a predetermined operation for two input values IN1 and IN2 as two output values OUT1 and OUT2.

Note that although the RNN cell processor 22 includes the one RNN cell 31, the RNN cell processor 22 may include two or more RNN cells 31. Alternatively, the number of RNN cells 31 may be the same as the number of layers, described below.

The input value IN1 of the RNN cell 31 is i_{l, t}, where l represents a layer, and t represents a step. The input value IN2 of the RNN cell 31 is a hidden state h_{l, t-1}. The output value OUT1 of the RNN cell 31 is a hidden state h_{l, t}, to be an input value IN1 (i.e., i_{l+1, t}) in a step tin a subsequent layer (l+1). The output value OUT2 of the RNN cell 31 is a hidden state h_{l, t}, to be an input value IN2 of the RNN cell 31 in a subsequent step (t+1) in the same layer.

The step t is also referred to as a time step, is a number that increases every time one sequential data is inputted to the RNN and a hidden state is updated, and is a virtual unit that is assigned as a hidden state or an input/output index and is not necessarily the same as an actual time.

As illustrated in FIG. 3, the RNN cell 31 can read out various types of parameters (indicated by a dotted line) used for an RNN operation from the off-chip memory 12 and hold the parameters within the RNN cell 31. Examples of the parameters include a weight parameter w and a bias value b in each RNN operation for each layer, described below.

Note that the RNN cell 31 may be realized by software to be executed by a central processing unit (CPU).

Although the RNN cell 31 performs an operation corresponding to each of the layers, described below, the stream data SD is sequentially inputted as the input value IN1 of the RNN cell 31 in the first layer. The RNN cell 31 performs a predetermined operation, generates the output values OUT1 and OUT2 that are each the hidden state h_{l, t} as an operation result, and outputs the generated output values to the state buffer 21.

Each of the output values OUT1 and OUT2 obtained in each of the layers is stored in a predetermined storage region in the state buffer 21. The state buffer 21 is a line buffer, for example.

Since the state buffer 21 is provided in the ISP 11, the RNN cell 31 can write and read out data to and from the state buffer 21 at high speed. The RNN cell 31 stores a hidden state h obtained by performing a predetermined operation in the state buffer 21. The state buffer 21 is an SRAM including a line buffer, and is a buffer storing at least data corresponding to the number of stream data.

The RNN cell 31 can perform a plurality of layer operations. The RNN cell 31 can perform a first layer operation for performing a predetermined operation upon receiving stream data SD, a second layer operation for performing a predetermined operation upon receiving a hidden state h as an operation result of the predetermined operation in the first layer, a third layer operation for performing a predetermined operation upon receiving a hidden state h as an operation result of the predetermined operation in the second layer, and the like.

A predetermined operation in the RNN cell 31 will be described. In an l-th layer operation, the RNN cell 31 sets an input value IN1 as pixel data i and outputs output values OUT1 and OUT2 using an activation function tan h that is a nonlinear function as a predetermined operation in a step t. The output values OUT1 and OUT2 are each a hidden state hₜ. As illustrated in FIG. 4, the hidden states h_{l, t} is calculated by the following equation (1):

h_{l,t}=tan h(w_{l,ih}i_{l,t}+w_{l,hh}h_{l,t-1}+bl) (1)

where w_{l, ih}, and w_{l, hh} are respectively weight parameters expressed by the following equations (2) and (3):

$$\begin{matrix}{w}_{I , ih} ∈ {R}^{e \times d} & ( 2 ) \\ {w}_{I , hh} ∈ {R}^{e \times e} & ( 3 )\end{matrix}$$

where R^{e×d} and R^{e×e} are respectively spaces by execution columns of e rows and d columns and e rows and e columns, which both indicate that R^{e×d} and R^{e×e} are respectively real rows and columns

The input value (pixel data i_{l, t}) and the output value (hidden state h_{l, t}) are respectively expressed by the following equations (4) and (5):

$$\begin{matrix}{i}_{I , t} ∈ {R}^{d} & ( 4 ) \\ {h}_{I , t} ∈ {R}^{e} & ( 5 )\end{matrix}$$

where R^{d} represents a d-dimensional real space, and R^{e} represents an e-dimensional real space, which both indicate that R^{d} and R^{e} are respectively real vectors.

A value of each of the weight parameters in the above-described nonlinear function is optimized by RNN leaning.

The pixel data i_{l, t} is an input vector, is a three-dimensional vector when an RGB image, for example, is inputted, and is the number of its channels in an intermediate feature map. The hidden states h_{l, t} is an output vector. In the equations, d and e are respectively dimensions of the input vector and an output vector, l is a layer number and an index of sequential data, and b is a bias value.

Note that although the RNN cell 31 generates two output values OUT1 and OUT2 having the same value from an input value IN1 and an input value IN2 as an output value from a previous pixel and outputs the generated output values in FIG. 4, the RNN cell 31 may output two output values OUT1 and OUT2 different from each other.

In the second layer operation, the RNN cell 31 uses an input value IN1 as an output value OUT1 in the first layer, and outputs output values OUT1 and OUT2 using an activation function tan h that is a non-linear function as a predetermined operation.

When the third and fourth layer operations are further performed subsequently to the second layer operation, the RNN cell 31 uses an input value IN1 as an output value OUT1 in a previous layer, and outputs output values OUT1 and OUT2 using an activation function tan h that is a nonlinear function as a predetermined operation in the third and fourth layer operations, for example, like in the second layer operation.

### (Function)

Next, an operation of the ISP 11 will be described. An example including three layers will be described. As described above, the pixel stream decoder 23 outputs as input image data IG stream data SD in which a plurality of pixel data from a pixel at a left end to a pixel at a right end of a first row L1, a plurality of pixel data from a pixel at a left end to a pixel at a right end of a second row L2, . . . , a plurality of pixel data from a pixel at a left end to a pixel at a right end of a data column LL (i.e., L6) as a last row are arranged in this order (an order indicated by an arrow A) (FIG. 5).

In the first layer, a first input value IN1 to the RNN cell 31 is first data (i.e., a pixel in a first column of a first row of the input image data IG) in the stream data SD, and an input value IN2 is a predetermined default value.

In the first layer, the RNN cell 31 performs a predetermined operation when receiving the two input values IN1 and IN2 at a first step t1, and outputs output values OUT1 and OUT2. The output values OUT1 and OUT2 are stored in a predetermined storage region in the state buffer 21. The output value OUT1 in the step t1 in the first layer is read out of the state buffer 21 in a first step t1 in the subsequent second layer, and is used as an input value IN1 of the RNN cell 31. In the first layer, the output value OUT2 in the step t1 is used as an input value IN2 in a subsequent step t2.

Similarly to the above, an output value OUT1 in each of steps after that in the first layer is read out of the state buffer 21 in a corresponding step in the subsequent second layer, and is used as an input value IN1 of the RNN cell 31. In the first layer, an output value OUT2 in each of the steps after that in the first layer is read out of the state buffer 21 in a subsequent step, and is used as an input value IN2 of the RNN cell 31.

When a predetermined operation in the first layer for each of the pixel data in the stream data SD is finished, processing in the second layer is performed.

When a predetermined operation in the first layer for first pixel data is finished, processing corresponding to a first pixel in the second layer is performed.

In the second layer, a plurality of output values OUT1 obtained from a first step to a last step in the first layer are sequentially inputted to the RNN cell 31 as an input value IN1. The RNN cell 31 performs a predetermined operation in the second layer in an order from the first step to the last step in the first layer, like the processing in the first layer.

When a predetermined operation in the second layer for each of the output values OUT1 in the first layer is finished, processing in the third layer is performed.

When a predetermined operation in the second layer for first pixel data is finished, processing corresponding to a first pixel in the third layer is performed.

In the third layer, a plurality of output values OUT1 obtained from a first step to a last step in the second layer are sequentially inputted to the RNN cell 31 as an input value IN1. The RNN cell 31 performs a predetermined operation in the third layer in an order from the first step to the last step in the second layer, like the processing in the second layer.

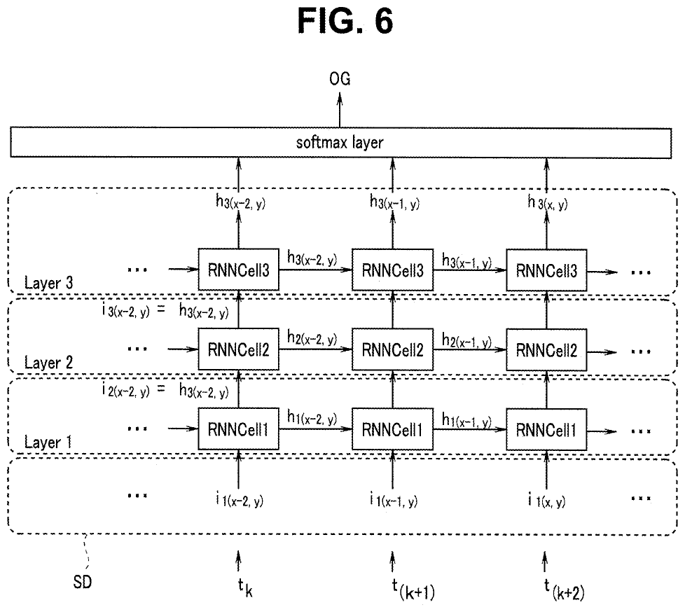

FIG. 6 is a diagram for describing a processing order by the RNN cell 31 of a plurality of pixel values included in the input image data IG. FIG. 6 illustrates a flow of input values IN1 and IN2 to be inputted to the RNN cell 31 and output values OUT1 and OUT2 to be outputted from the RNN cell 31 in a plurality of steps. The RNN cell 31 is indicated as RNNCell1 in a first layer, the RNN cell is indicated as RNNCell2 in a second layer, and the RNN cell is indicated as RNNCell3 in a third layer.

FIG. 6 illustrates only a flow of processing for pixel data in a column x and previous columns (x−1) and (x−2) of a row y in input image data IG.

As illustrated in FIG. 6, an input value IN1 of RNNCell1 in a column (x−2) in a first layer (layer 1) is pixel data inputted in a step tk. An input value IN2 of RNNCell1 in the column (x−2) in the first layer is an output value OUT2 of RNNCell1 in a column (x−3) in the first layer. An output value OUT1 of RNNCell1 in the column (x−2) in the first layer is an input value IN1 of RNNCell2 in the column (x−2) in a second layer. An output value OUT2 of RNNCell1 in the column (x−2) in the first layer is an input value IN2 of RNNCell1 in a column (x−1) in the first layer.

Similarly, an input value IN1 of RNNCell1 in the column (x−1) in the first layer is pixel data inputted in a step t₍ₖ₊₁₎. The input value IN2 of RNNCell1 in the column (x−1) in the first layer is the output value OUT2 of RNNCell1 in the column (x−2) in the first layer. An output value OUT1 of RNNCell1 in the column (x−1) in the first layer is an input value IN1 of RNNCell2 in the column (x−1) in the second layer. An output value OUT2 of RNNCell1 in the column (x−1) in the first layer is an input value IN2 of RNNCell1 in a column (x) in the first layer.

An input value IN1 of RNNCell1 in the column (x) in the first layer is pixel data inputted in a step t₍ₖ₊₂₎. The input value IN2 of RNNCell1 in the column (x) in the first layer is the output value OUT2 of RNNCell1 in the column (x−1) in the first layer. An output value OUT1 of RNNCell1 in the column (x) in the first layer is an input value IN1 of RNNCell2 in the column (x) in the second layer. The output value OUT2 of RNNCell1 in the column (x−1) in the first layer is used as an input value IN2 of RNNCell1 in a subsequent step.

As described above, the RNN cell 31 in the RNN processor 22 sequentially performs RNN operations, respectively, for the inputted plurality of pixel data, and stores information about a hidden state in the state buffer 21. The hidden state is an output of the RNN cell 31.

The input value IN1 of RNNCell2 in the column (x−2) in the second layer (layer 2) is the output value OUT1 of RNNCell1 in the column (x−2) in the first layer. An input value IN2 of RNNCell2 in the column (x−2) in the second layer is an output value OUT2 of RNNCell2 in the column (x−3) in the second layer. An output value OUT1 of RNNCell2 in the column (x−2) in the second layer is an input value IN1 of RNNCell3 in the column (x−2) in the third layer. An output value OUT2 of RNNCell2 in the column (x−2) in the second layer is an input value IN2 of RNNCell2 in the column (x−1) in the second layer.

Similarly, the input value IN1 of RNNCell2 in the column (x−1) in the second layer is the output value OUT1 of RNNCell1 in the column (x−1) in the first layer. The input value IN2 of RNNCell2 in the column (x−1) in the second layer is the output value OUT2 of RNNCell2 in the column (x−2) in the second layer. An output value OUT1 of RNNCell2 in the column (x−1) in the second layer is an input value IN1 of RNNCell3 in the column (x−1) in the third layer. An output value OUT2 of RNNCell2 in the column (x−I) in the second layer is an input value IN2 of RNNCell2 in the column (x) in the second layer.

The input value IN1 of RNNCell2 in the column (x) in the second layer is the output value OUT1 of RNNCell1 in the column (x) in the first layer. The input value IN2 of RNNCell2 in the column (x) in the second layer is the output value OUT2 of RNNCell2 in the column (x−1) in the second layer. An output value OUT1 of RNNCell2 in the column (x) in the second layer is an input value IN1 of RNNCell3 in the column (x) in the third layer. An output value OUT2 of RNNCell2 in the column (x) in the second layer is used as an input value IN2 of RNNCell2 in a subsequent step.

The input value IN1 of RNNCell3 in the column (x−2) in the third layer (layer 3) is the output value OUT1 of RNNCell2 in the column (x−2) in the second layer. An input value IN2 of RNNCell3 in the column (x−2) in the third layer is an output value OUT2 of RNNCell3 in the column (x−3) in the third layer. An output value OUT1 of RNNCell3 in the column (x−2) in the third layer is inputted to a softmax layer, and output image data OG is outputted from the softmax layer. An output value OUT2 of RNNCell3 in the column (x−2) in the third layer is an input value IN2 of RNNCell3 in the column (x−1) in the third layer.

Similarly, the input value IN1 of RNNCell3 in the column (x−1) in the third layer is the output value OUT1 of RNNCell2 in the column (x−1) in the second layer. The input value IN2 of RNNCell3 in the column (x−1) in the third layer is the output value OUT2 of RNNCell3 in the column (x−2) in the third layer. An output value OUT1 of RNNCell3 in the column (x−1) in the third layer is inputted to the softmax layer, and output image data OG is outputted from the softmax layer. An output value OUT2 of RNNCell3 in the column (x−1) in the third layer is an input value IN2 of RNNCell3 in the column (x) in the third layer.

The input value IN1 of RNNCell3 in the column (x) in the third layer is the output value OUT1 of RNNCell2 in the column (x) in the second layer. The input value IN2 of RNNCell3 in the column (x) in the third layer is the output value OUT2 of RNNCell3 in the column (x−1) in the third layer. An output value OUT1 of RNNCell3 in the column (x) in the third layer is inputted to the softmax layer, and output image data OG is outputted from the softmax layer. An output value OUT2 of RNNCell3 in the column (x) in the third layer is used as an input value IN2 of RNNCell3 in a subsequent step.

Therefore, an output of the third layer is data representing the plurality of output values OUT1 obtained in the plurality of steps. The output of the third layer is inputted to the softmax layer. An output of the softmax layer is converted into image data in y rows and x columns, and the image data are stored as the output image data OG in the off-chip memory 12.

As described above, the RNN cell processor 22 performs a recursive neural network operation using at least one of a plurality of pixel data in image data and a hidden state as an operation result of an RNN operation stored in the state buffer 21. The RNN processor 22 can execute a plurality of layers as a processing unit configured to perform an RNN operation a plurality of times. The plurality of layers include a first processing unit (first layer) configured to perform an RNN operation upon receiving a plurality of pixel data and a second processing unit (second layer) configured to perform an RNN operation upon receiving data representing a hidden state obtained in the first processing unit (first layer).

Note that a value of each of weight parameters in a nonlinear function in an RNN operation is optimized by RNN leaning, as described above.

As descried above, according to the above-described embodiment, a CNN is replaced with an RNN, to perform predetermined processing for image data.

Therefore, the image processing apparatus according to the present embodiment converts image data into stream data SD, to sequentially perform an RNN operation, unlike in a method of holding image data in the off-chip memory 12 and then performing a kernel operation while sliding a window of a predetermined size for the entire image data. Thus, neural network operation processing can be performed with a small latency and at low cost.

### (Modification 1)

In the above-described embodiment, the image data composed of the plurality of pixels in the plurality of rows and the plurality of columns is converted into the stream data SD, and the pixel value in the first row and the first column to the pixel value in the last row and the last column are sequentially inputted as the input value IN1 of the one RNN cell 31.

However, in the image data, the pixel value of the pixel in the first column of each of the rows and the pixel value of the pixel in the last column of the previous row differ in tendency of a feature value.

In Modification 1, a line end cell configured to not set an output value OUT2 in a last column of each of rows to a first input value IN2 in a subsequent row as it is but change the output value OUT2 to a predetermined value and then set the output value OUT2 to a first input value IN2 of an RNN cell 31 in the subsequent row is added.

As the line end cell, the RNN cell 31 may be used by changing an execution content of the RNN cell 31 such that an operation of a nonlinear function different from the above-described nonlinear function is performed, or a line end cell 31a as an operation cell different from the RNN cell 31 provided in an RNN cell processor 22 may be used, as indicated by a dotted line in FIG. 3.

A value of each of weight parameters of the nonlinear function in the line end cell is also optimized by RNN leaning.

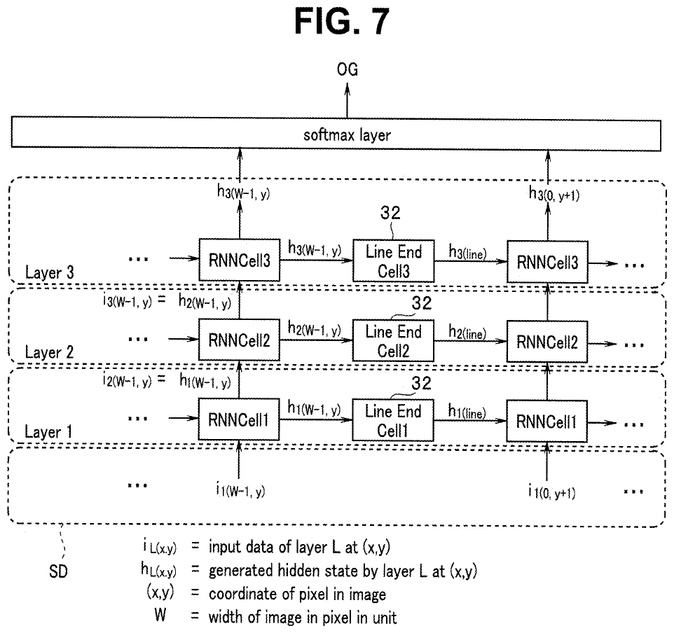

FIG. 7 is a diagram for describing a processing order by the line end cell 31a of respective output values OUT2 in a last column of rows. Each of the rows of image data has W pixel values. In other words, the image data has W columns.

As illustrated in FIG. 7, after the RNN cell 31 performs a predetermined operation for pixel data in a last column (W−1) obtained when a first column is set to 0, and then the output value OUT2 is inputted to the line end cell 31a.

As illustrated in FIG. 7, the line end cell 31a performs processing for an output value OUT2 of the RNN cell 31 in the last column (W−1) of each of the rows for each of layers. In FIG. 7, the line end cell 31a in the first layer is indicted as a LineEndCell1, the line end cell 31a in the second layer is indicated as a LineEndCell2, and the line end cell 31a in the third layer is indicated as a LineEndCell3.

In the first layer, the line end cell 31a in the y-th row inputs an output value OUT2 (h_{1(W-1, y)}) of RNNCell1 in the last column of the y-th row in the first layer, and sets a hidden state h₁₍ₗᵢₙₑ₎ as an output value of an operation result as an input value IN2 of RNNCell1 in the subsequent (y+1)-th row.

Similarly, in the second layer, the line end cell 31a in the y-th row also inputs an output value OUT2 (h_{2(W-1, y)}) of RNNCell2 in the last column of the y-th row in the second layer, and sets a hidden state h₂₍ₗᵢₙₑ₎ as an output value of an operation result as an input value IN2 of RNNCell2 in the subsequent (y+1)-th row.

Similarly, in the third layer, the line end cell 31a in the y-th row also inputs an output value OUT2 (h_{3(W-1, y)}) of RNNCell3 in the last column of the y-th row in the third layer, and sets a hidden state h₃₍ₗᵢₙₑ₎ as an output value of an operation result as an input value IN2 of RNNCell3 in the subsequent (y+1)-th row.

As described above, the RNN cell processor 22 includes, when the image data is composed of pixel data in n rows and m columns, a line end cell 31a configured to perform a predetermined operation for a hidden state between two adjacent rows.

Therefore, the line end cell 31a is provided in a transition between the rows in each of the layers. The line end cell 31a performs processing for changing an inputted output value OUT2, and sets the changed output value as an input value IN2 of the RNN cell 31 when processing for the subsequent row is performed.

As described above, the line end cell 31a changes the output value OUT2 in the last column of each of the rows so that an effect of a difference in tendency of a feature value between a last pixel value in each of the rows and a first pixel value in the subsequent row can be eliminated, and thus an accuracy of noise removal can be expected to be improved.

### (Modification 2)

In the above-described embodiment, the input value IN1 of the RNN cell 31 is acquired in the step that matches among all the layers. On the other hand, in Modification 2, an input value IN1 of an RNN cell 31 is not acquired in a step that matches among layers but is acquired with a delay of an offset such that an RNN operation has a similar receptive field to a receptive field in a CNN. In other words, an image processing apparatus according to Modification 2 is configured such that an RNN operation is performed with an offset among the layers.

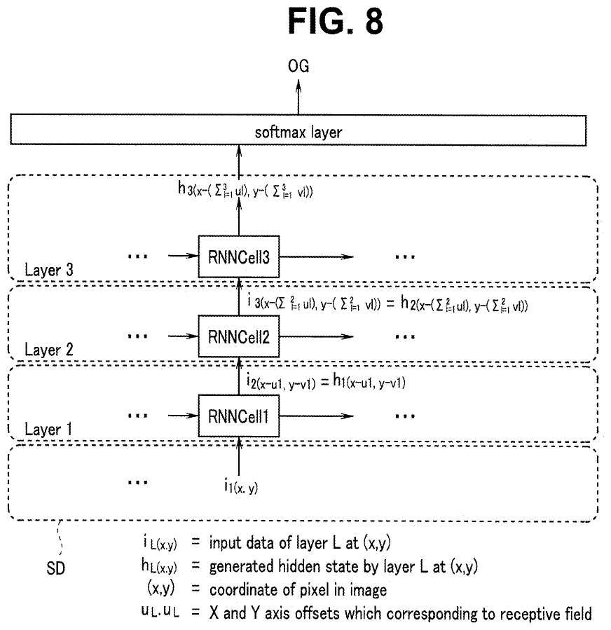

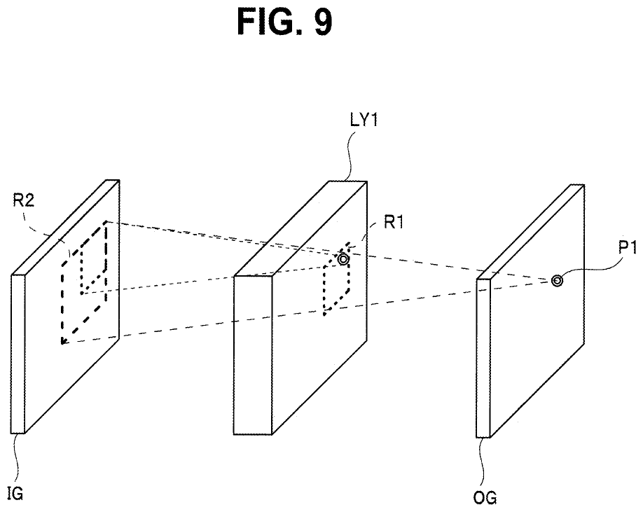

FIG. 8 is a diagram for describing an order of processing by the RNN cell 31 of a plurality of pixel values included in input image data IG according to Modification 2.

As illustrated in FIG. 8, pixel data i in stream data SD is sequentially processed in a first layer. However, in a second layer, an output value OUT1 of RNNCell1 is used with a delay of an offset u1 in an x-direction of an image and with a delay of an offset v1 in a y-direction of the image as an input value IN1 of RNNCell2. Note that offset information is written into an off-chip memory 12, and is written as a parameter into an RNN cell processor 22 from the off-chip memory 12.

In FIG. 8, the input value IN1 of RNNCell2 is expressed by the following equation (6):

i_{2(x-u1,y-v1)}=h_{1(x-u1,y-v1)} (6)

Further, in a third layer, an output value OUT1 of RNNCell1 is used with a delay of an offset (u1+u2) in the x-direction of the image and with a delay of an offset (v1+v2) in the y-direction of the image as an input value IN1 of RNNCell3.

In other words, in FIG. 8, the input value IN1 of RNNCell3 is expressed by the following equation (7):

$${i}_{3 ( x - ( {\sum }_{I = 1}^{2} ul ) , y - ( {\sum }_{I = 1}^{2} vl ) )} = {h}_{2 ( x - ( {\sum }_{I = 1}^{2} ul ) , y - ( {\sum }_{I = 1}^{2} vl ) )} \qquad ( 7 )$$

An output value OUT1 of RNNCell3 in the third layer is expressed by the following equation (8):

$${h}_{3 ( x - ( {\sum }_{I = 1}^{3} ul ) , y - ( {\sum }_{I = 1}^{3} vl ) )} \qquad ( 8 )$$

FIG. 9 is a diagram for describing a receptive field in a CNN. The receptive field is a range of an input value that affects a kernel operation. Output image data OG is generated by a layer LY1 configured to perform a CNN operation for the input image data 1G. In this case, a range R2 wider than a kernel size R1 in the layer LY1 affects an output value P1 of output image data. Therefore, in the CNN, when the CNN operation is repeated, a receptive field as a range of an input value to be directly or indirectly referred to is widened because an output value is obtained.

On the other hand, in the above-described embodiment, the RNN operation is performed. Thus, in an operation step for each of the layers, a range of a result of an RNN operation performed before the step can be said to be a receptive field.

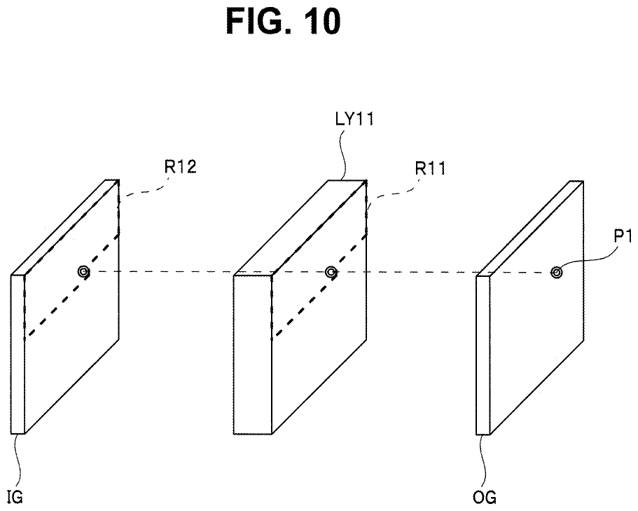

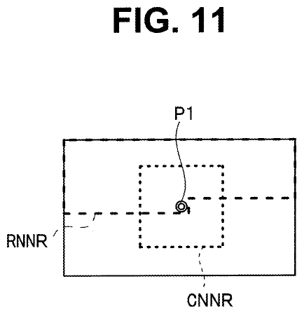

FIG. 10 is a diagram for describing a receptive field in the above-described embodiment. FIG. 11 is a diagram for describing a difference between respective ranges of receptive fields in a CNN and an RNN. When the RNN cell 31 performs an RNN operation for stream data SD in input image data IG in a layer LY11, a range R12 indicated by a dotted line in the input image data IG in FIG. 10 is a receptive field. A receptive field of an output value P1 in the layer LY11 is a range R11 of an operation result in a step before an operation step of the output value P1.

Accordingly, in the above-described embodiment, an operation result of a pixel value around the output value P1, like in the CNN illustrated in FIG. 9, is not used in the RNN operation. As illustrated in FIG. 11, a receptive field RNNR in the RNN differs from a receptive field CNNR in the CNN.

In the above-described embodiment, to perform an RNN operation considering a receptive field, like in the CNN, the RNN cell 31 shifts a range of an input value IN1 to be read out of the state buffer 32 such that an input value IN1 of the RNN cell 31 used in a step in a layer is a hidden state h (an output value) of the RNN cell 31 in a step different from the step in a previous layer. In other words, data representing a hidden state obtained in the first layer as a first processing unit is given to the RNN processor 22 from the state buffer 21 in a step delayed by a set offset in a second layer as a second processing unit.

As illustrated in FIG. 8, in the second layer, the input value IN1 of RNNCell2 is the output value OUT1 at a pixel position offset by u1 in the x-direction and by v1 in the y-direction. In other words, the output value OUT1 in an RNN operation in the first layer at a pixel position shifted by respective predetermined values (u1, v1) in a horizontal direction and a vertical direction of image data is the input value IN1 of RNNCell2 in the second layer.

In the third layer, the input value IN1 of RNNCell3 is an output value OUT1 offset by (u1+u2) in the x-direction and (v1+v2) in the y-direction in an output image in the second layer.

The output value OUT1 of RNNCell3 is an output value offset by (u1+u2+u3) in the x-direction and (v1+v2+v3) in the y-direction in the output image in the second layer.

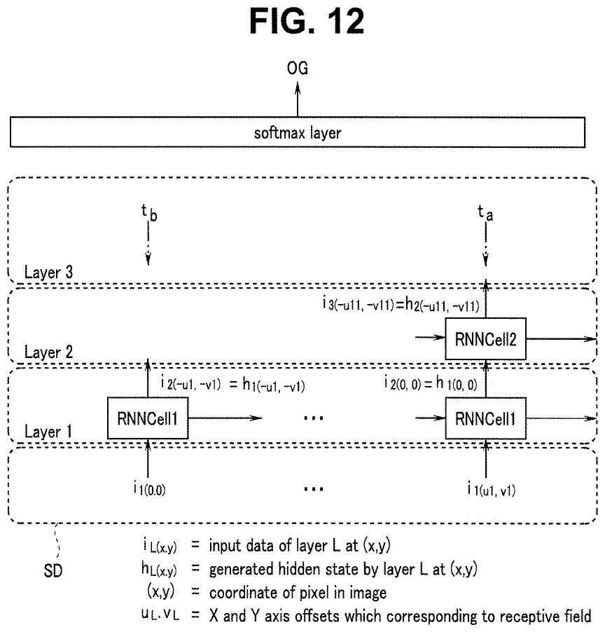

FIG. 12 is a diagram for describing an input step of the RNN cell 31. As illustrated in FIG. 12, an output value OUT1 of RNNCell1 using first pixel data i1 (0, 0) as an input value IN1 is used as an input value IN1 in a step tₐ corresponding to an offset value in a second layer. The offset value in the second layer is a step difference for an acquisition step of pixel data in stream data SD in a first layer. The offset value is a value corresponding to a step difference from a position (0, 0) of a pixel in a first row and a first column to a position (u1, v1) of a pixel in a u1-th row and v1-th column.

Therefore, in the first step tₐ in the second layer, an input value IN1 of RNNCell2 is an output value OUT1 in a step delayed by an offset value from a first step t_{b} in the first layer.

Further, although the offset value may be the same among the layers, the offset value differs for each of the layers. As illustrated in FIG. 12, as an output value OUT1 of the RNN cell 31 in the step tₐ in a third layer, an offset value corresponding to a pixel position (u11, v11) is an input value IN1 of the RNN cell 31 in the third layer.

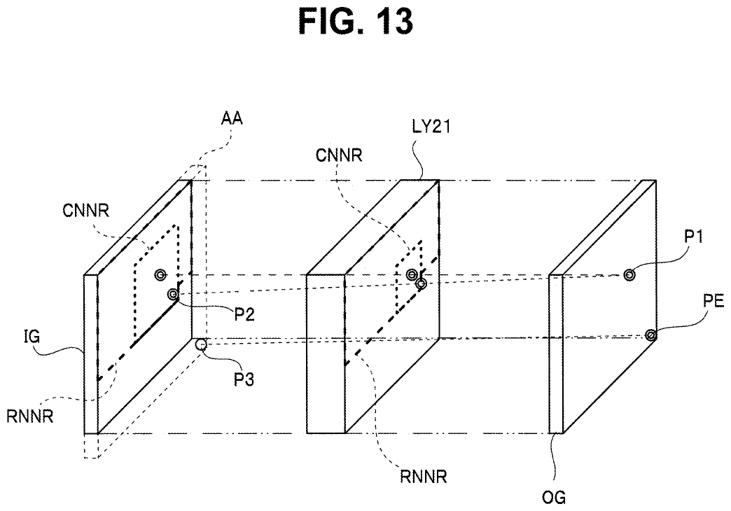

FIG. 13 is a diagram for describing a setting range of a receptive field in Modification 2. If an offset value of an input value IN in a layer LY21 is provided, a predetermined region AA is added to input image data IG by padding. As illustrated in FIG. 13, an output value P1 is outputted upon being affected by an input value P2 in a receptive field RNNR. Therefore, the output value P1 is affected by an output value of a receptive field RNNR in the layer LY21, and the receptive field RNNR in the layer LY21 is affected by an input value of a receptive field RNNR in the input image data 1G. An output value PE is affected by an input value P3 in the added region AA.

As described above, when the offset in the input step of the input value IN1 in each of the RNN operations is provided for each of the layers, a similar receptive field to the receptive field in the CNN can also be set in image processing using the RNN.

As described above, according to the above-described embodiment and modifications, there can be provided an image processing apparatus that can be implemented with a small latency and at low cost.

Note that although the above-described RNN cell 31 is a simple RNN, the RNN cell 31 may have a structure such as an LSTM (long short term memory) network or a GRU (gated recurrent unit).

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. An image processing apparatus comprising:
a first processor configured to receive image data;
a buffer provided in the first processor; and
a second processor configured to perform a recursive neural network operation using at least one of a plurality of pixel data in the image data and an operation result of the recursive neural network operation stored in the buffer.

2. The image processing apparatus according to claim 1, wherein
the operation result of the recursive neural network operation is a hidden state.

3. The image processing apparatus according to claim 1, wherein
the plurality of pixel data are sequentially inputted to the recursive neural network processor, and
the recursive neural network processor sequentially performs the recursive neural network operation for the inputted plurality of pixel data, and stores the operation result in the buffer.

4. The image processing apparatus according to claim 3, wherein
the second processor can execute a plurality of layers as a processing unit configured to perform the recursive neural network operation a plurality of times.

5. The image processing apparatus according to claim 4, wherein
the plurality of layers include a first processing unit configured to perform the recursive neural network operation by inputting the plurality of pixel data, and a second processing unit configured to perform the recursive neural network operation by inputting the operation result obtained in the first processing unit.

6. The image processing apparatus according to claim 5, wherein
the operation result obtained in the first processing unit is given to the second processor from the state buffer in a step delayed by a set offset in the second processing unit.

7. The image processing apparatus according to claim 3, wherein
the image data includes pixel data in n rows and m columns, and
the second processor performs a predetermined operation for the operation result between adjacent rows.
